(19) United States
(12) Patent Application Publication
(10) Pub. No.: US 2023/0124881 A1
(43) Pub. Date: Apr. 20, 2023

(54) TECHNIQUES FOR EXTRACTION OF VECTORIZED CONTENT OF AN OIL AND GAS PLAY WITHIN AN UNSTRUCTURED FILE

(71) Applicant: Landmark Graphics Corporation, Houston, TX (US)

(72) Inventors: Ian A. Fletcher, Didcot (GB); Daniel James David Slidel, Tilehurst (GB); Benjamin Patrick Ivko, Abingdon (GB)

(21) Appl. No.: 17/047,272

(22) PCT Filed: Jan. 14, 2020
(86) PCT No.: PCT/US2020/013457

§ 371 Date: Oct. 13, 2020

(51) Int. Cl. G06F 40/166; G06V 30/422; G06V 10/25; G06V 10/44; G06F 16/93; G06F 40/151

(52) U.S. Cl. CPC G06F 40/166; G06V 30/422; G06V 10/25; G06V 10/44; G06F 16/93; G06F 40/151; G06V 2201/02

(57) ABSTRACT

A method includes retrieving an unstructured document and defining an area of interest of the unstructured document that visually represents geological formation information. The method also includes extracting a set of vectorized polygons from the area of interest. Additionally, the method includes assigning properties from the unstructured document to each of the vectorized polygons in the set of vectorized polygons. Further, the method includes assigning a coordinate reference frame to the set of vectorized polygons and generating a user-interactive document from the set of vectorized polygons.

### TECHNICAL FIELD

The present disclosure relates generally to techniques for extracting oil and gas play content from a file and, more particularly (although not necessarily exclusively), to automatically extracting vectorized content of an oil and gas play from an unstructured file.

### BACKGROUND

Vectorized content may be generated as oil and gas play cross-section images to represent various information associated with subsurface geology. Legacy content files may include static or unstructured content that represents the vectorized content. For example, the legacy files, such as PDF documents, may include content that is not interactive. Because the legacy files include this static or unstructured content, interpretation of the files may be inaccurate or tedious. Further, the static content may not include standardized information across multiple files, which may result in comprehension fatigue by a reader of multiple files.

### BRIEF DESCRIPTION OF THE DRAWINGS

FIG. 1 is a schematic view of a computing system for generating an interactive geospatially-enabled database platform from a set of documents that include static content according to one example of the present disclosure.

FIG. 2 is an example of an unstructured document used to generate the interactive geospatially-enabled database platform of FIG. 1 according to one example of the present disclosure.

FIG. 3 is an example of an interactive document generated from the unstructured file of FIG. 2 according to one example of the present disclosure.

FIG. 4 is a flowchart of a process for generating the interactive document of FIG. 3 according to one example of the present disclosure.

FIG. 5 is an example of the interactive geospatially-enabled database platform generated from the interactive documents of FIG. 3 according to one example of the present disclosure.

FIG. 6 is a flowchart of a process for generating the interactive geospatially-enabled database platform of FIG. 5 according to one example of the present disclosure.

FIG. 7 is a schematic view of a computing system for implementing certain embodiments of the present disclosure according to one example of the present disclosure.

### DETAILED DESCRIPTION

Certain aspects and examples of the present disclosure relate to automatically extracting vectorized content of an oil and gas play from an unstructured file. In an example, the unstructured file may be any document that does not provide a capability for user interaction. For example, a user of the unstructured file may be unable to edit text or images or to select objects within the document. The vectorized content may include content in the unstructured file that is represented by digital graphics (e.g., images) positioned within the unstructured file. The digital graphics may represent formation cross-sections (e.g., geological formation layer indications) of an oil and gas play. In some examples, extracting the vectorized content from the unstructured file may enable generation of an interactive representation of the digital graphics in a user-interactive document. Further, by combining the vectorized content extracted from multiple unstructured files, an interactive representation of a formation region may be generated as an interactive geospatially-enabled database platform.

Automated extraction of the vectorized content from unstructured files may enable extraction of information from a number of unstructured files into a standardized format. The standardized format may enable data processing and geo-locating techniques to be applied to the digital graphics of the unstructured files. This may enable use of the vectorized content from the unstructured files in mapping technologies and visualization or analytical technologies.

Some aspects of the techniques provide a process for converting images within the unstructured files into sets of vectorized polygons. This conversion may enable transposition of the vectorized polygons into a range of native spatial data formats to generate a mapping representation of the vectorized polygons. Further, meaningful attributes may be assigned to the vectorized polygons to preserve information provided in the unstructured files. By generating the vectorized polygons, large quantities of legacy data may be accessible and interactive within a content-specific user interface. The geospatial data associated with the vectorized polygons may be “dynamic” data that is capable of interaction with a user of the user interface. Additionally, complex geological interpretations from the unstructured files may be more intuitive to users within the user interface than in the unstructured file. In particular, the ability to query and filter vectorized polygons may be provided.

Illustrative examples are given to introduce the reader to the general subject matter discussed herein and are not intended to limit the scope of the disclosed concepts. The following sections describe various additional features and examples with reference to the drawings in which like numerals indicate like elements, and directional descriptions are used to describe the illustrative aspects, but, like the illustrative aspects, should not be used to limit the present disclosure.

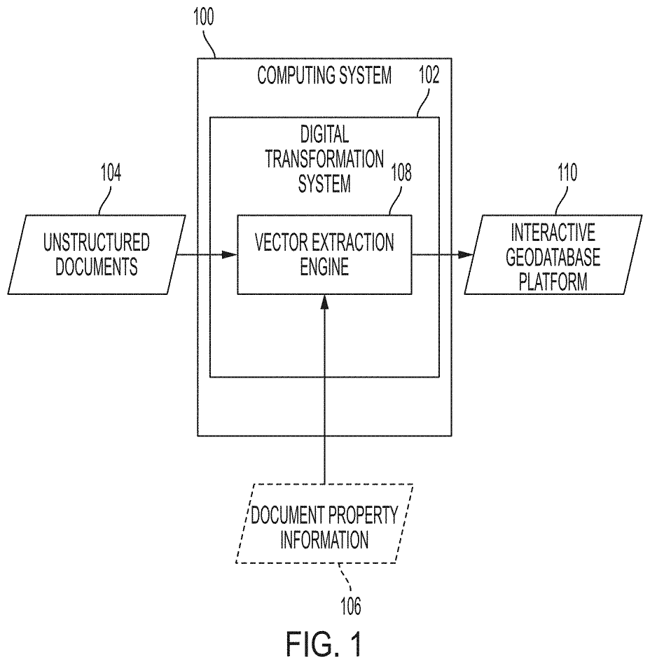

FIG. 1 is an example of a computing environment including a computing system 100 executing a digital transformation system 102 with the capability to extract vectorized content from unstructured documents 104 according to one example of the present disclosure. While FIGS. 1-7 refer to extraction of vectorized content from unstructured documents 104, vectorized content may be extracted in a similar manner from other types of unstructured files. The unstructured documents 104 may be described as documents with static content. For example, the content of the unstructured documents 104, which may include PDF or image documents, may not be interactive or selectable. The digital transformation system 102 may be implemented in software (e.g., via code, instructions, programs executed by one or more processors of computing system 100). The computing environment depicted in FIG. 1 is merely an example and is not intended to unduly limit the scope of claimed embodiments. One of ordinary skill in the art would recognize many possible variations, alternatives, and modifications. For example, in some implementations, the digital transformation system 102 can be implemented using more or fewer process engines or subsystems than those shown in FIG. 1, may combine two or more process engines or subsystems, or may have a different configuration or arrangement of process engines or subsystems.

A user may use the computing system 100 to receive or otherwise access the unstructured document 104. The unstructured document 104 may be a single or multi-paged document. In some examples, the unstructured document 104 may have a particular layout. For example, the unstructured document 104 may include an image that represents formation characteristics of a cross-section of a formation. A legend within the unstructured document 104 may provide information about the characteristics depicted in the image. The unstructured document 104 may also include text information about the characteristics of the formation or geospatial coordinates associated with the depicted cross-section of the formation. Collectively, the legend and the text information of the document may be referred to as document property information 106.

The unstructured documents 104 received or accessed at the digital transformation system 102 may include a standard format. For example, individual colors or patterns representing formation layers (i.e., facies types) in an image within the unstructured documents 104 may represent the same formation characteristic across all of the unstructured documents 104. In such an example, the document property information 106 may be obtained from information stored within the computing system 100, rather than obtained directly from the unstructured documents 104 themselves (e.g., from a legend of the unstructured document 104).

When the unstructured documents 104 are received or otherwise accessed by the digital transformation system 102, areas of interest of the unstructured documents 104 may be identified. The areas of interest may include image portions of the unstructured documents 104. The areas of interest may be identified automatically by the digital transformation system 102 (e.g., by identifying boxes or sections within the unstructured document that are likely images), or the areas of interest may be identified manually by a user of the digital transformation system 102 (e.g., using a point and click operation within a user interface).

A vector extraction engine 108 may then identify the individual polygons within the areas of interest to extract vectorized polygons from the areas of interest. The vectorized polygon may represent a polygon that is sized to fill a space represented by a particular characteristic in the area of interest of the unstructured document 104. For example, each vectorized polygon extracted from the unstructured document 104 may represent individual facies types in a cross-section of a formation.

Each of the vectorized polygons extracted by the vector extraction engine 108 may be assigned a property based on the document property information 106. For example, when a particular vectorized polygon is shaded or patterned in a manner that represents a property of the polygon, the vector extraction engine 108 may reference the document property information 106 to identify the property. The identified property may be assigned to the vectorized polygon by the vector extraction engine 108. The properties may be identified based on a color, a pattern, a label, a font, a size, a nearest neighbor, or any other distinguishing features of the unstructured document 104 that enable identification of the content-specific properties.

In an example, the digital transformation system 102 may also apply a topology clean-up workflow to identify and repair any defects with the extracted vectorized polygons. For example, the topology clean-up workflow may identify gaps or overlapping areas between vectorized polygons and adjust the polygons accordingly to fill-in any undesired gaps or remove any undesired overlapping areas. In some examples, the topology clean-up workflow may identify and flag faults for a user to correct.

The vectorized polygons may be converted from an XY reference system (i.e., relative to a position on a document page) of the unstructured documents 104 into a coordinate reference system. The coordinate reference system may be a real-world representation of the location depicted in the areas of interest of the unstructured documents 104. By converting the vectorized polygons into the coordinate reference system, the vectorized polygons can provide real-world frames of reference for comparison between vectorized polygons originating from different unstructured documents 104.

Each of the vectorized polygons extracted by the vector extraction engine 108 may be compiled within an interactive geospatially-enabled database platform 110. The interactive geospatially-enabled database platform 110 may provide a mechanism for a user to view and analyze geospatial content. In this manner, information from a set of unstructured documents 104 may be available for user interaction within the interactive geospatially-enabled database platform 110. Further, in some examples, the vectorized polygons extracted from the unstructured documents 104 may represent formation layers in a horizontal plane (e.g., as opposed to the vertical plane described above).

In the interactive geospatially-enabled database platform 110, the vectorized polygons may provide an indication of reservoir or seal data within a geological map. In an example, a user may be able to filter source rocks within a formation cross-section by age or formation name. Other information associated with the unstructured document 104 (e.g., other geological data) may also be filtered. Additionally, supplemental data, such as a well log, may be may be linked to the model or play cross-section within the interactive geospatially-enabled database platform 110.

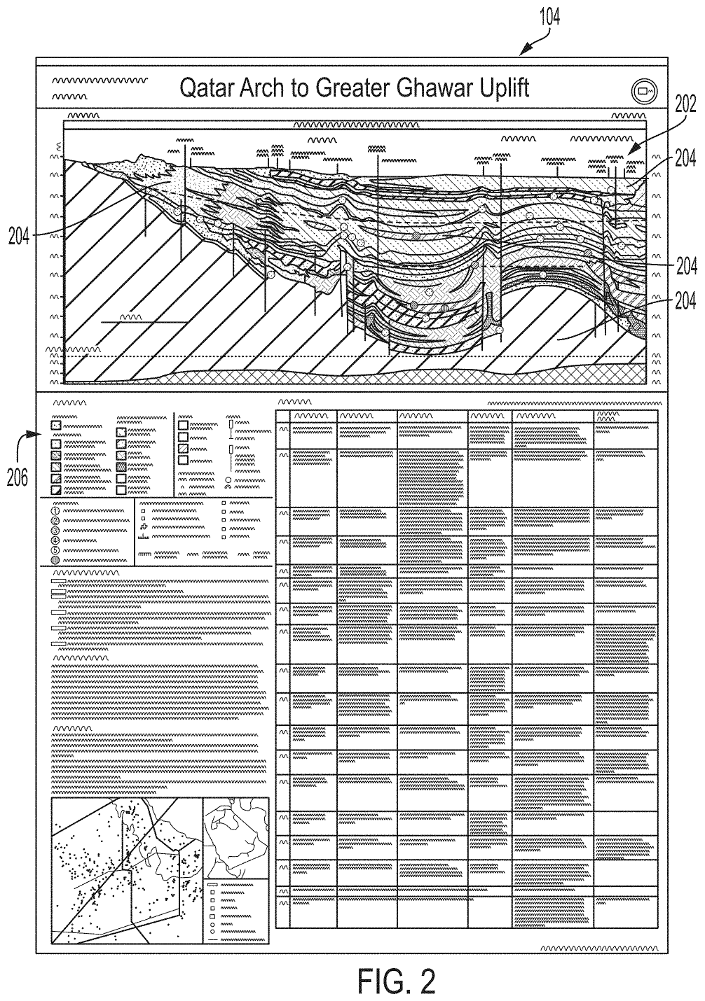

FIG. 2 is an example of an unstructured document 104 used to generate the interactive geospatially-enabled database platform 110 according to one example of the present disclosure. As described above with respect to FIG. 1, the unstructured document 104 may include an area of interest 202. The area of interest 202 may include an area of the unstructured document 104 that includes in image. As illustrated, the area of interest 202 represents a play cross-section of a geological basin. Other examples of the area of interest 202 may include chronostratigraphic charts. As illustrated, various facies types are depicted by polygons 204. Each of the polygons 204 may include a different color or pattern, as indicated in a legend 206 (i.e., the document property information 106 of FIG. 1). The varying colors are patterns may represent varying formation properties associated with the portions of the formation represented by the polygons 204.

Each of the polygons 204 of the area of interest 202 may be extracted from the unstructured document 104 in a vectorized form. The extracted, vectorized polygons may be assigned the formation properties represented by the legend 206 and compiled into the interactive geospatially-enabled database platform 110. The compilation of the vectorized polygons may be interactive and adjustable within the interactive geospatially-enabled database platform 110. Further, geospatial information (e.g., geographical coordinates) included in the unstructured document 104 may provide the vectorized polygons with a geographical reference frame for use within the interactive geospatially-enabled database platform 110.

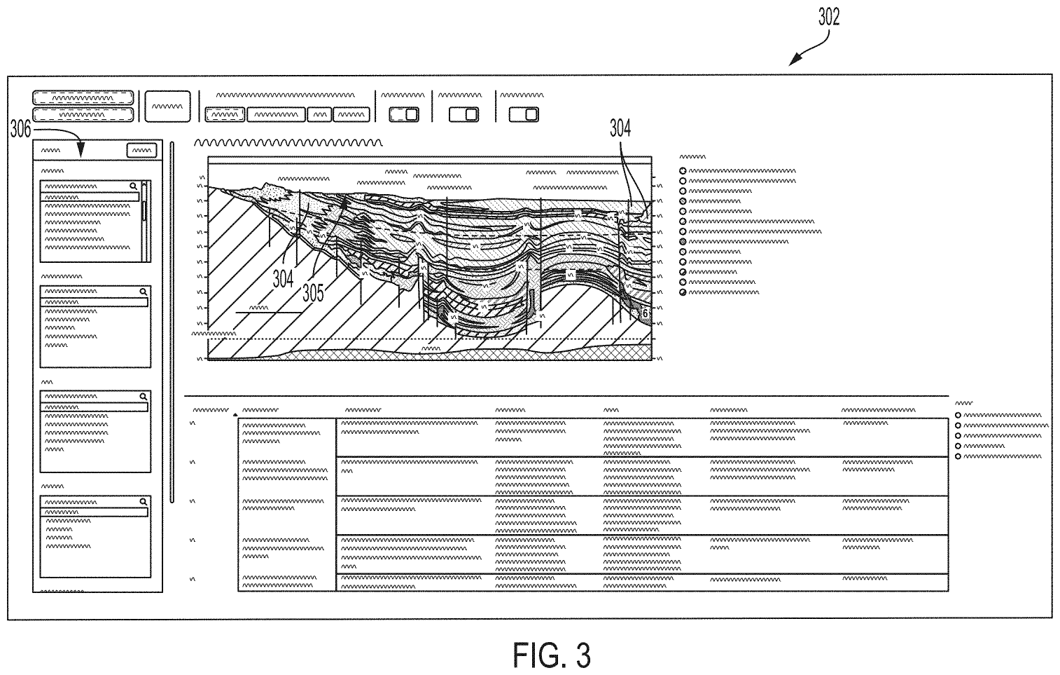

FIG. 3 is an example of an interactive document 302 generated from the static document of FIG. 2 according to one example of the present disclosure. In an example, the interactive document 302 may be output on a display as part of the interactive geospatially-enabled database platform 110. The term “document” may refer to any file that is displayable on the display. In an example, the interactive document 302 may refer to an interactive dashboard front-end interface of the geospatially-enabled data base platform 110. In another example, the interactive document 302 may refer to a webpage of a website. The interactive document 302 may also be used to describe other file types that are capable of displaying the interactive features of the interactive document 302. Vectorized polygons 304, which were extracted from the area of interest 202 in FIG. 2, may be depicted as interactive elements. For example, the formation property assigned to one of the vectorized polygons 304 may be displayed as a cursor 305 hovers over one of the vectorized polygon 304.

Additionally, a filter section 306 of the interactive document 302 may provide a mechanism for a user of the interactive geospatial platform 110 to filter out vectorized polygons 304 from the display. For example, a user may filter the display based on lithology, tectonic phase, formation age, formation maturity, or any other formation properties that were extracted from the unstructured documents 104. By filtering out vectorized polygons 304, the interactive geospatial platform 110 can ignore geological information that is not relevant to a particular problem to reduce clutter in the display.

As illustrated, the interactive document 302 may represent information associated with the vectorized polygons 304 from a single unstructured document 104. In other examples, the interactive document 302 may represent information associated with vectorized polygons 304 from multiple unstructured document 104 (e.g., where each unstructured document 104 focuses on a different formation property). Further, information associated with the vectorized polygons 304 may be stored in an accompanying table or spreadsheet. For example, the vectorized polygons 304 may be associated with tabularized data by linking the vectorized polygons 304 to a unique ID. In such an example, the interactivity of the interactive document 302 allows for data to be “live linked.” That is, the interactivity of the interactive document 302 may remain up-to-date automatically upon addition of new data to a back-end database (i.e., not added directly to the document itself).

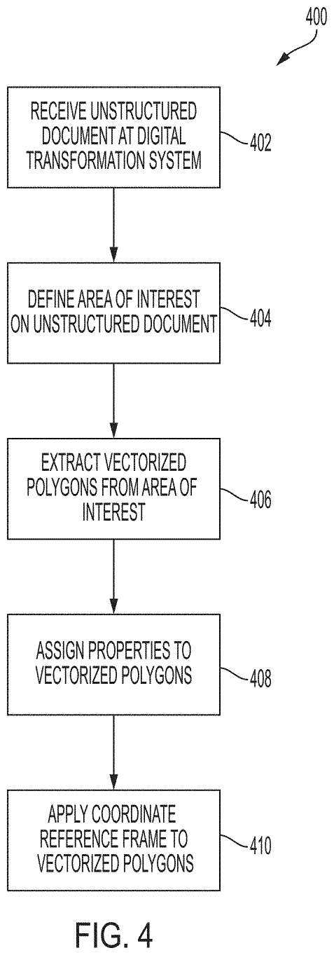

FIG. 4 is a flowchart of a process 400 for generating the interactive document 302 according to one example of the present disclosure. For illustrative purposes, the process 400 is described with reference to certain examples depicted in the figures. Other implementations, however, are possible.

At block 402, the process 400 involves receiving the unstructured document 104 at the digital transformation system 102. The unstructured document 104 may be retrieved from memory storing a queue of unstructured documents 104 awaiting digital transformation. In an additional example, a user can manually upload the unstructured document 104 to the digital transformation system 102. As described above, the unstructured document 104 may include the area of interest 202 that depicts formation information about a play cross-section of a formation.

At block 404, the process 400 involves defining the area of interest 202 of the unstructured document 104. The digital transformation system 102 may automatically identify the area of interest 202, or a user of the computing system 100 may manually identify the bounds of the area of interest 202 within the unstructured document 104. In an example, automatically identifying the area of interest 202 may result from an algorithm that locates a frame within the unstructured document 104 that includes dimensions that corresponds with dimensions that are known for the area of interest 202 (e.g., a rectangular frame that meets known height and width dimensions). Other examples of automatically identifying the area of interest 202 within the unstructured document 104 can also be used.

At block 406, the process 400 involves extracting the vectorized polygons 304 from the area of interest 202 of the unstructured document 104. The vectorized polygons 304 may represent the shape and location of the polygons 204 of the area of interest 202. Each of the polygons 204 within the area of interest 202 may represent a location of a formation property, as represented by the unstructured document 104.

At block 408, the process 400 involves assigning properties to the vectorized polygons 304 that were extracted from the area of interest 202. As discussed above, the polygons 204 of the unstructured document 104 may represent locations of formation properties (e.g., facie types) within a play cross-section of the formation. The legend 206 of the unstructured document, or a standard legend stored within the memory of the computing system 100 for a particular type of document, may be queried based on the characteristics (e.g., color, pattern, etc.) of a polygon 204 in the unstructured document 104. The query may identify the corresponding formation characteristic represented by the polygon 204. The identified formation characteristic may be assigned to the corresponding vectorized polygon 304 for use in the interactive geospatially-enabled database platform 110.

At block 410, the process 400 involves applying a geographic coordinate reference frame to the vectorized polygons 304 extracted from the unstructured document 104. In an example, the unstructured document 104 may include an indication of a geographic coordinate reference frame of the area of interest 202. The digital transformation engine 102 may identify the geographic coordinate reference frame of the area of interest 202 and assign a corresponding geographic coordinate reference frame to each of the vectorized polygons 304 extracted from the unstructured document 104. The assigned geographic coordinate reference frame may provide a reference frame for appropriately locating the vectorized polygons 304 within the interactive geospatially-enabled database platform 110.

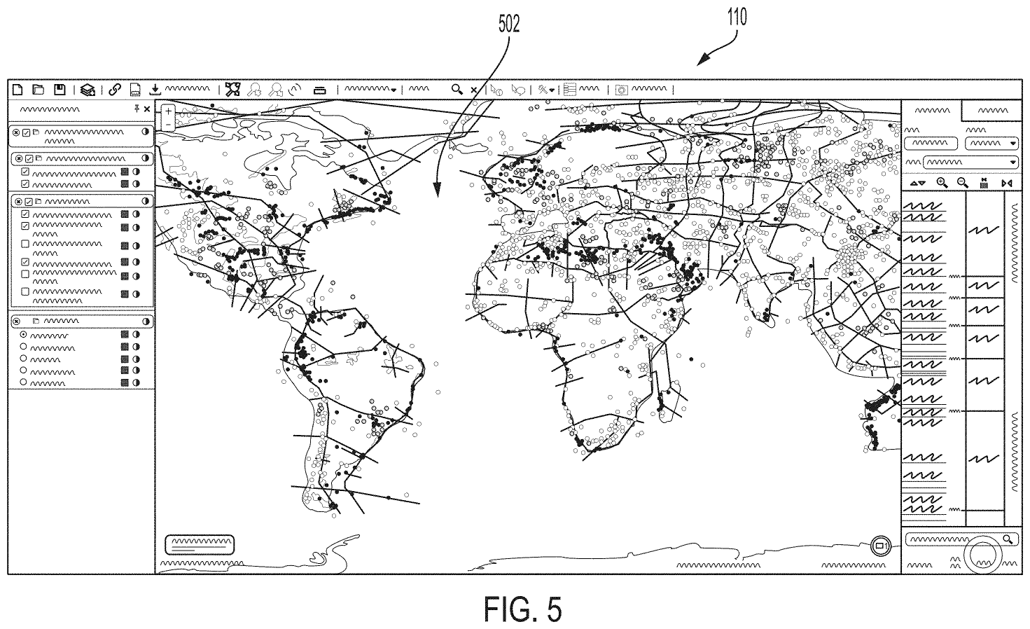

FIG. 5 is an example of the interactive geospatially-enabled database platform 110 generated from the interactive documents 302 according to one example of the present disclosure. The interactive geospatially-enabled database platform 110 may provide an interface for selecting and viewing individual interactive documents 302 that are generated from the unstructured documents 104. The geographic coordinate reference frames assigned to the vectorized polygons 304 may provide an indication of where in a world map 502 the vectorized polygons 304 of particular interactive documents 302 are located geographically.

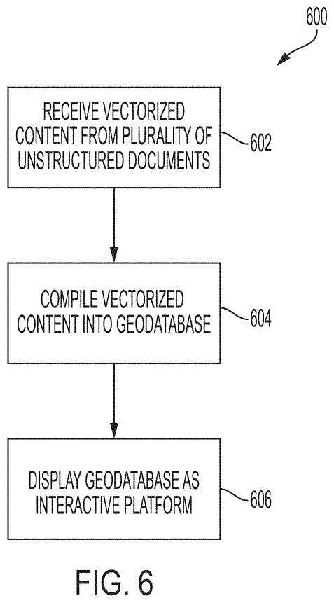

FIG. 6 is a flowchart of a process 600 for generating the interactive geospatially-enabled database platform 110 according to one example of the present disclosure. In an example, the process 600 may occur iteratively as new vectorized polygons 304 are extracted from the unstructured documents 304. For illustrative purposes, the process 600 is described with reference to certain examples depicted in the figures. Other implementations, however, are possible.

At block 602, the process 600 involves receiving vectorized content from a plurality of unstructured documents 104. As discussed above, the vector extraction engine 108 of the digital transformation system 102 may extract vectorized polygons 304 from the unstructured documents 104. The vectorized polygons 304 represent play cross-sections of formation properties at varying geographical coordinate locations. In additional examples, the vectorized polygons 304 may represent other types of information displayed in other types of images and documents. For example, the vectorized polygons 304 may represent information depicted in a chronostratigraphic chart.

At block 604, the process 600 involves compiling the vectorized content into the interactive geospatially-enabled database platform 110. As the vectorized content (e.g., the set of vectorized polygons 304) is provided to the interactive geospatially-enabled database platform 110, the interactive geospatially-enabled database platform 110 updates content available for delivery to and interaction with a user. Further, multiple unstructured documents 104 may depict the same geographical location of the play cross-section, but the unstructured documents 104 depict different formation properties. When the vectorized polygons 304 representing such unstructured documents 104 are compiled at the interactive geospatially-enabled database platform 110, a number of layers of information may be present for the play cross-section associated with that geographical location.

At block 606, the process 600 involves displaying the interactive geospatially-enabled database platform 110. That is, the interactive geospatially-enabled database platform 110 is provided to a user such that the user is able to interact with the information presented within the interactive geospatially-enabled database platform 110.

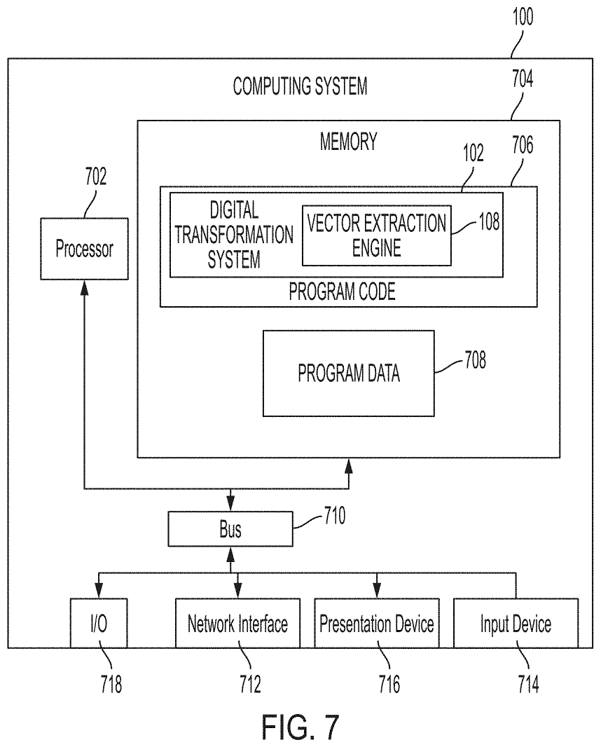

Any suitable computing system or group of computing systems can be used for performing the operations described herein. For example, FIG. 7 depicts an example of the computing system 100. The computing system 100 may implement the digital transformation system 102 and the vector extraction engine 108. In an example, a computing system 100 having devices similar to those depicted in FIG. 7 (e.g., a processor, a memory, etc.) may combine the one or more operations and data stores that may be operated as separate subsystems.

The depicted example of the computing system 100 includes a processor 702 communicatively coupled to one or more memory devices 704. The processor 702 may execute computer-executable program code stored in a memory device 704, access information stored in the memory device 704, or both. Examples of the processor 702 may include a microprocessor, an application-specific integrated circuit (“ASIC”), a field-programmable gate array (“FPGA”), or any other suitable processing device. The processor 702 can include any number of processing devices, including a single processing device.

The memory device 704 may include any suitable non-transitory computer-readable medium for storing program code 706, program data 708, or both. A computer-readable medium can include any electronic, optical, magnetic, or other storage device capable of providing a processor with computer-readable instructions or other program code. Non-limiting examples of a computer-readable medium include a magnetic disk, a memory chip, a ROM, a RAM, an ASIC, optical storage, magnetic tape or other magnetic storage, or any other medium from which a processing device can read instructions. The instructions may include processor-specific instructions generated by a compiler or an interpreter from code written in any suitable computer-programming language, including, for example, C, C++, C#, Visual Basic, Java, Python, Perl, JavaScript, and ActionScript. In various examples, the memory device 704 can be volatile memory, non-volatile memory, or a combination thereof.

The computing system 100 executes program code 706 that configures the processor 702 to perform one or more of the operations described herein. Examples of the program code 706 include, in various embodiments, the digital transformation system 102, which may include the vector extraction engine 108, or any other suitable systems or subsystems that perform one or more operations described herein (e.g., one or more development systems for configuring an interactive user interface). The program code 706 may be resident in the memory device 704 or any suitable computer-readable medium and may be executed by the processor 702 or any other suitable processor.

The processor 702 may be an integrated circuit device that can execute the program code 706. The program code 706 can be for executing an operating system, an application system or subsystem (e.g., the digital transformation system 102 or the vector extraction engine 108), or both. When executed by the processor 702, the instructions may cause the processor 702 to perform operations of the program code 706. When being executed by the processor 702, the instructions may be stored in a system memory, possibly along with data being operated on by the instructions. The system memory can be a volatile memory storage type, such as a Random Access Memory (RAM) type. The system memory is sometimes referred to as Dynamic RAM (DRAM) though need not be implemented using a DRAM-based technology. Additionally, the system memory can be implemented using non-volatile memory types, such as flash memory.

In some embodiments, one or more memory devices 704 may store the program data 708 that includes one or more datasets and models described herein. Examples of these datasets include document data, layout change information, text data, etc. In some embodiments, one or more of data sets, models, and functions are stored in the same memory device (e.g., one of the memory devices 704). In additional or alternative embodiments, one or more of the programs, data sets, models, and functions may be stored in different memory devices 704 accessible via a data network. One or more buses 710 may also be included in the computing system 100. The buses 710 may communicatively couple one or more components of a respective one of the computing system 100.

In some embodiments, the computing system 100 also includes a network interface device 712. The network interface device 712 may include any device or group of devices suitable for establishing a wired or wireless data connection to one or more data networks. Non-limiting examples of the network interface device 712 include an Ethernet network adapter, a modem, and/or the like. The computing system 100 may be able to communicate with one or more other computing devices via a data network using the network interface device 712.

The computing system 100 may also include a number of external or internal devices, an input device 714, a presentation device 716, or other input or output devices. For example, the computing system 100 is shown with one or more input/output (“I/O”) interfaces 718. An I/O interface 718 can receive input from input devices or provide output to output devices. An input device 714 can include any device or group of devices suitable for receiving visual, auditory, or other suitable input that controls or affects the operations of the processor 702. Non-limiting examples of the input device 714 include a touchscreen, a mouse, a keyboard, a microphone, a separate mobile computing device, etc. A presentation device 716 can include any device or group of devices suitable for providing visual, auditory, or other suitable sensory output. Non-limiting examples of the presentation device 716 include a touchscreen, a monitor, a speaker, a separate mobile computing device, etc.

Although FIG. 7 depicts the input device 714 and the presentation device 716 as being local to the computing device that executes the digital transformation system 102, other implementations are possible. For instance, in some embodiments, one or more of the input device 714 and the presentation device 716 can include a remote client-computing device that communicates with the digital transformation system 102 via the network interface device 712 using one or more data networks described herein.

In some aspects, a system and method for extracting vectorized content from an unstructured file are provided according to one or more of the following examples:

As used below, any reference to a series of examples is to be understood as a reference to each of those examples disjunctively (e.g., “Examples 1-4” is to be understood as “Examples 1, 2, 3, or 4”).

Example 1 is a system comprising: a processing device; and a memory device comprising instructions that are executable by the processing device for causing the processing device to: receive an unstructured document; define an area of interest of the unstructured document that visually represents geological formation information; extract a set of vectorized polygons from the area of interest; assign properties from the unstructured document to each vectorized polygon in the set of vectorized polygons; and assign a coordinate reference frame to the set of vectorized polygons; generating a user-interactive document from the set of vectorized polygons.

Example 2 is the system of example 1, further comprising: a display device, wherein the instructions are further executable for causing the processing device to: output the user-interactive document to the display device, wherein the user-interactive document comprises interactive information about each vectorized polygon of the set of vectorized polygons.

Example 3 is the system of example 2, wherein the user-interactive document is output to the display device as a component of an interactive geospatially-enabled database platform, and wherein the interactive geospatially-enabled database platform comprises a plurality of additional user-interactive documents generated from a plurality of additional unstructured documents.

Example 4 is the system of examples 1-3, wherein the geological formation information of the area of interest comprises visual indication of a plurality of formation layers.

Example 5 is the system of example 4, wherein each vectorized polygon of the set of vectorized polygons represents a formation layer of the plurality of formation layers.

Example 6 is the system of examples 1-5, wherein the instructions are further executable for causing the processing device to: identify the properties from a legend of the unstructured document, wherein the properties comprise formation characteristics.

Example 7 is the system of examples 1-6, wherein the instructions are further executable for causing the processing device to: repair defects corresponding to the set of vectorized polygons, wherein the defects comprise gaps between two or more vectorized polygons of the set of vectorized polygons.

Example 8 is the system of example 7, wherein the defects further comprise area overlap between two or more vectorized polygons of the set of vectorized polygons.

Example 9 is a method, comprising: receiving, by a digital transformation system, an unstructured document; defining, by the digital transformation system, an area of interest of the unstructured document; extracting, by the digital transformation system, a set of vectorized polygons from the area of interest; assigning, by the digital transformation system, properties from the unstructured document to each vectorized polygon in the set of vectorized polygons; assigning, by the digital transformation system, a coordinate reference frame to the set of vectorized polygons; generating, by the digital transformation system, a user-interactive document from the set of vectorized polygons; and displaying the user-interactive document in an interactive platform comprising a plurality of additional user-interactive documents.

Example 10 is the method of example 9, wherein the area of interest comprises a visual indication of a set of geological formation layers or a chronostratigraphic chart.

Example 11 is the method of example 10, wherein each vectorized polygon of the set of vectorized polygons is extracted from a formation layer of a set of formation layers represented in the area of interest.

Example 12 is the method of examples 9-11, further comprising: detecting, by the digital transformation system, the properties from a legend within the unstructured document, wherein the properties comprise formation characteristics.

Example 13 is the method of examples 9-12, further comprising: compiling the user-interactive document with a plurality of additional user-interactive documents to generate the interactive platform.

Example 14 is the method of examples 9-13, further comprising: repairing defects corresponding to positioning of the set of vectorized polygons within the user-interactive document.

Example 15 is the method of example 14, wherein the defects comprise gaps or overlapping areas between vectorized polygons.

Example 16 is a non-transitory computer-readable medium comprising program code that is executable by a processing device for causing the processing device to: receive an unstructured document; define an area of interest of the unstructured document comprising geological formation information; extract a set of vectorized polygons from the area of interest; assign properties from the unstructured document to each vectorized polygon in the set of vectorized polygons; assign a coordinate reference frame to the set of vectorized polygons; and generate a user-interactive document from the set of vectorized polygons.

Example 17 is the non-transitory computer-readable medium of example 16, wherein the area of interest comprises an image within the unstructured document.

Example 18 is the non-transitory computer-readable medium of example 17, wherein the image within the unstructured document comprises a set of formation layers, and wherein each vectorized polygon of the set of vectorized polygons represents a formation layer of the set of formation layers.

Example 19 is the non-transitory computer-readable medium of examples 16-18, the program code further executable by the processing device for causing the processing device to: detect the properties from a legend within the unstructured document, wherein the properties comprise formation characteristics.

Example 20 is the non-transitory computer-readable medium of examples 16-19, the program code further executable by the processing device for causing the processing device to: compile the user-interactive document with a plurality of additional user-interactive documents to generate an interactive geospatially-enabled database platform.

The foregoing description of certain examples, including illustrated examples, has been presented only for the purpose of illustration and description and is not intended to be exhaustive or to limit the disclosure to the precise forms disclosed. Numerous modifications, adaptations, and uses thereof will be apparent to those skilled in the art without departing from the scope of the disclosure.

What is claimed is:

1. A system comprising:
a processing device; and
a memory device comprising instructions that are executable by the processing device for causing the processing device to:
receive an unstructured document;
define an area of interest of the unstructured document that visually represents geological formation information;
extract a set of vectorized polygons from the area of interest;
assign properties from the unstructured document to each vectorized polygon in the set of vectorized polygons;
assign a coordinate reference frame to the set of vectorized polygons; and
generate a user-interactive document from the set of vectorized polygons.

2. The system of claim 1, further comprising:
a display device, wherein the instructions are further executable for causing the processing device to:
output the user-interactive document to the display device, wherein the user-interactive document comprises interactive information about each vectorized polygon of the set of vectorized polygons.

3. The system of claim 2, wherein the user-interactive document is output to the display device as a component of an interactive geospatially-enabled database platform, and wherein the interactive geospatially-enabled database platform comprises a plurality of additional user-interactive documents generated from a plurality of additional unstructured documents.

4. The system of claim 1, wherein the geological formation information of the area of interest comprises visual indication of a plurality of formation layers.

5. The system of claim 4, wherein each vectorized polygon of the set of vectorized polygons represents a formation layer of the plurality of formation layers.

6. The system of claim 1, wherein the instructions are further executable for causing the processing device to:
identify the properties from a legend of the unstructured document, wherein the properties comprise formation characteristics.

7. The system of claim 1, wherein the instructions are further executable for causing the processing device to:
repair defects corresponding to the set of vectorized polygons, wherein the defects comprise gaps between two or more vectorized polygons of the set of vectorized polygons.

8. The system of claim 7, wherein the defects further comprise area overlap between two or more vectorized polygons of the set of vectorized polygons.

9. A method, comprising:
receiving, by a digital transformation system, an unstructured document;
defining, by the digital transformation system, an area of interest of the unstructured document;
extracting, by the digital transformation system, a set of vectorized polygons from the area of interest;
assigning, by the digital transformation system, properties from the unstructured document to each vectorized polygon in the set of vectorized polygons;
assigning, by the digital transformation system, a coordinate reference frame to the set of vectorized polygons;
generating, by the digital transformation system, a user-interactive document from the set of vectorized polygons; and
displaying the user-interactive document in an interactive platform comprising a plurality of additional user-interactive documents.

10. The method of claim 9, wherein the area of interest comprises a visual indication of a set of geological formation layers or a chronostratigraphic chart.

11. The method of claim 10, wherein each vectorized polygon of the set of vectorized polygons is extracted from a formation layer of a set of formation layers represented in the area of interest.

12. The method of claim 9, further comprising:
detecting, by the digital transformation system, the properties from a legend within the unstructured document, wherein the properties comprise formation characteristics.

13. The method of claim 9, further comprising:
compiling the user-interactive document with a plurality of additional user-interactive documents to generate the interactive platform.

14. The method of claim 9, further comprising:
repairing defects corresponding to positioning of the set of vectorized polygons within the user-interactive document.

15. The method of claim 14, wherein the defects comprise gaps or overlapping areas between vectorized polygons.

16. A non-transitory computer-readable medium comprising program code that is executable by a processing device for causing the processing device to:
receive an unstructured document;
define an area of interest of the unstructured document comprising geological formation information;
extract a set of vectorized polygons from the area of interest;
assign properties from the unstructured document to each vectorized polygon in the set of vectorized polygons;
assign a coordinate reference frame to the set of vectorized polygons; and
generate a user-interactive document from the set of vectorized polygons.

17. The non-transitory computer-readable medium of claim 16, wherein the area of interest comprises an image within the unstructured document.

18. The non-transitory computer-readable medium of claim 17, wherein the image within the unstructured document comprises a set of formation layers, and wherein each vectorized polygon of the set of vectorized polygons represents a formation layer of the set of formation layers.

19. The non-transitory computer-readable medium of claim 16, the program code further executable by the processing device for causing the processing device to:
detect the properties from a legend within the unstructured document, wherein the properties comprise formation characteristics.

20. The non-transitory computer-readable medium of claim 16, the program code further executable by the processing device for causing the processing device to:
compile the user-interactive document with a plurality of additional user-interactive documents to generate an interactive geospatially-enabled database platform.
